(19) United States
(12) Patent Application Publication
(10) Pub. No.: US 2010/0109697 A1
(43) Pub. Date: May 6, 2010

(54) PROBE CARD, NEEDLES OF PROBE CARD, AND METHOD OF MANUFACTURING THE NEEDLES OF PROBE CARD

(75) Inventor: Joon-Seok Oh, Cheongju-si (KR)

Correspondence Address: Jefferson IP Law, LLP, 1130 Connecticut Ave., NW, Suite 420, Washington, DC, 20036, US

(73) Assignee: IM CO., LTD., Anyang-si, Gyeonggi-do (KR)

(21) Appl. No.: 12/595,771

(22) PCT Filed: Jul. 9, 2007
(86) PCT No.: PCT/KR2007/003316

§ 371 Date: Oct. 13, 2009

(30) Foreign Application Priority Data
Apr. 11, 2007 (KR) 1020070035424

(51) Int. Cl. G01R 31/02

(52) U.S. Cl. 324/761

(57) ABSTRACT

A probe card for use in the test of the semiconductor devices, a needle of the probe card, and a method of manufacturing the needle are disclosed. This invention is to strengthen the beam portion of the needle, to reduce the contact area between a probing portion and a pad of a wafer die, and to prevent the test apparatus from malfunctioning. The needle of a probe card includes: a probing portion for contacting a pad of a wafer die at a certain pin pressure; a soldered portion soldered to a circuit board of the probe card, for transmitting an electrical signal to the probing portion; and a beam portion integrally connecting the probing portion and the soldered portion and having elasticity to exhibit a certain pin pressure by which the probing portion 210 can elastically contact the pad of a wafer die. Here, the beam portion has undergone a plating process. The needle of a probe card can precisely contact the pad.

### TECHNICAL FIELD

The present invention relates to a test apparatus for semiconductor devices. More particularly, this invention relates to needles of a probe card and a method of the needles, which makes the needles of a probe card precisely touch pads of a wafer die and prevents the needles from twisting, thereby allowing electrical signals to be smoothly transmitted.

### BACKGROUND ART

In general, semiconductor devices are manufactured through a fabrication process where a pattern is formed on a wafer and through an assembly process where each semiconductor device is assembled from the patterned wafer.

Between the fabrication process and the assembly process, the semiconductor devices fabricated on the wafer each undergo an electrical die sorting (EDS) process for testing electrical features.

Here, the EDS process refers to a process to determine whether the semiconductor devices fabricated on the wafer fail. The EDS process tests semiconductor devices using a test apparatus that applies an electrical signal to the semiconductor devices on the wafer and analyzes a response electrical signal from the devices.

In order to transmit the electrical signals between the test apparatus and pads of the semiconductor devices, a probe card is used. The probe card is configured to include one or more needles that contact the pads connected to the semiconductor devices of the wafer. The test apparatus for testing semiconductor devices transmits/receives electrical signals to/from the pads through the needles of the probe card, thereby determining whether the semiconductor devices fail.

Recently, the semiconductor devices have become highly integrated and tiny, design rules of a pattern have also become more minute. As semiconductor devices are becoming smaller, the size of the pads of a wafer die, to which needles of a probe card are touched, are also becoming smaller. As the size of the pads of a wafer die becomes more minute, a problem occurs, which is that plated needles of a probe card do not correctly touched the pads. Such problems will be described in detail later.

FIG. 1 is a cross-sectional view depicting a conventional needle of a probe card.

The convention needle 100 of a probe card is formed to include a probing portion 110 and a beam portion 120, which are plated to form a plated portion 121. That is, the needle 100 undergoes a plating process such that the plated portion 121 can prevent it from deforming, bending or twisting and so forth. As a result of the plating process, the probing portion 110 of the needle 100 becomes blunt. But, since the size of the pads of a wafer has become minute as described above, the contact area between the blunt probing portion 110 and the pads (not shown) is relatively increased, which make the contact therebetween become imprecise.

Meanwhile, in order for the needle 100 to firmly contact the pad of a wafer die, the needle 100 undergoes pin pressure (which refers to the force applied to per unit area of pads by the ends of the needles). As semiconductor devices are increasingly highly integrated, the number of pads also increases, thereby requiring an increased number of needles 100. With the number of needles 100 increased, this increase in needles also increases the pressing force distributed to the respective needles 100. In order to maintain constant pin pressure, a force applied to the probe card with the needles must be increased.

However, since the conventional needle 100 with the plated portion 121 has a relatively large contact area of its probing portion 110, it must undergo a force, increased corresponding to the increased contact area, to keep a certain pin pressure constant. In that case, as the semiconductor devices are becoming highly integrated and minute, the number of needles 100 must be increased. As the number of the needles 100 is increased, a force applied to the probe card must be increased to maintain a certain pin pressure per needle. However, when the force applied to the needle 100 is increased, the test apparatus for testing semiconductor devices causes many problems.

### DISCLOSURE OF INVENTION

### Technical Problem

Therefore, the present invention has been made in view of the above problems, and it is an object of the present invention to provide a needle of a probe card and its manufacturing method that can maintain the straightness of a beam portion of the needle, which is plated, reduce the contact area between a probing portion and a pad of a wafer die, and prevent the test apparatus from malfunctioning.

It is another object of the present invention to provide a probe card that can prevent its needles from mutually interfering and smoothly test highly integrated semiconductor devices.

### Technical Solution

In accordance with a first aspect of the present invention, there is provided a needle of a probe card, which includes: a probing portion for contacting a pad of a wafer die at a certain pin pressure; a soldered portion soldered to a circuit board of the probe card, for transmitting an electrical signal to the probing portion; and a beam portion integrally connecting the probing portion and the soldered portion and having elasticity to exhibit a certain pin pressure by which the probing portion 210 can elastically contact the pad of a wafer die. Preferably, the beam portion undergoes a plating process.

In accordance with a second aspect of the present invention, there is provided a needle of a probe card, which includes: a probing portion for contacting a pad of a wafer die at a certain pin pressure; a soldered portion soldered to a circuit board of the probe card, for transmitting an electrical signal to the probing portion; and a beam portion integrally connecting the probing portion and the soldered portion and having elasticity to exhibit a certain pin pressure by which the probing portion 210 can elastically contact the pad of a wafer die. Preferably, the soldered portion and the beam portion undergo a plating process.

In accordance with a third aspect of the present invention, there is provided a method of manufacturing a needle of a probe card, which includes: coating a probing portion of a raw body of the needle with a photoresist to fabricate a first intermediate body; plating the first intermediate body to fabricating a second intermediate body; and removing the photoresist from the probing portion of the second intermediate body.

In accordance with a fourth aspect of the present invention, there is provided a method of manufacturing a needle of a probe card, which includes: coating a raw body of the needle with a photoresist to fabricate a first intermediate body; removing the photoresist from a beam portion and a probing portion of the first intermediate body of the needle to fabricate a second intermediate body; coating the probing portion of the second intermediate body of the needle with the photoresist to fabricate a third intermediate body; plating the third intermediate body of the body to fabricate a fourth intermediate body; and removing the photoresist from the fourth intermediate body of the needle.

*In accordance with a fifth aspect of the present invention, there is provided a method of manufacturing a needle of a probe card, which includes: coating a raw body of the needle with a photoresist to fabricate a first intermediate body of the needle; removing the photoresist from a beam portion and a soldered portion of the first intermediate body to fabricate a second intermediate body of the needle; coating the soldered portion of the second intermediate body with the photoresist to fabricate a third intermediate body of the needle; plating the third intermediate body to fabricate a fourth intermediate body of the needle; and removing the photoresist from the fourth intermediate body of the needle.

In accordance with a sixth aspect of the present invention, there is provided a probe card including: a substrate having a plurality of circuit patterns; and a plurality of needles electrically connected to the plurality of circuit patterns.

Each needle includes: a probing portion contacting a pad of a wafer die at a certain pin pressure; a soldered portion soldered to the substrate, for transmitting an electrical signal to the probing portion; and a beam portion integrally connecting the probing portion and the soldered portion and having an electricity to exhibit a certain pin pressure by which the probing portion 210 can elastically contact the pad of a wafer die. Here, the adjacent needles are aligned in such way that their distances between the soldered portion and the beam portion are located at different positions.

Preferably, the beam portions of the plurality of needles undergo a plating process.

Preferably, the beam portion of the needle and the adjacent beam portion of the adjacent needle are located at different positions, in which a top position of the beam portion and a bottom position of the adjacent beam portion are spaced apart a certain value.

### Advantageous Effects

As described above, the method of manufacturing a needle of a probe card has advantages in that: since the beam portion of the needle for a probe card undergoes a plating process, the needle can be prevented from twisting; since the contact area between the probing portion and the pad of a wafer die is relatively small, the needle can precisely contact the pad; with a relatively small elastic force of the beam portion, the needle can maintain a certain level of pin pressure to contact the pad without overworking a test apparatus; and since the soldered portion of the needle does not undergo a plating process, the needle can be easily replaced.

Also, the needle of the probe card according to the present invention can enhance precision contacting of the pad of a wafer die, can precisely contact the pad of a wafer die consistently, can be easily replaced with another one, and does not overwork a test apparatus.

In addition, since the probe card of the present invention can be configured by combining different types of needles whose intervals between the beam portion and soldered portion are different from each, it does not cause interference therebetween the needles and can be highly integrated.

### BRIEF DESCRIPTION OF THE DRAWINGS

The above and other objects, features, and other advantages of the present invention will be more clearly understood from the following detailed description taken in conjunction with the accompanying drawings, in which:

FIG. 1 is a cross-sectional view depicting a conventional needle of a probe card;

FIG. 2 is a cross-sectional view depicting a needle of a probe card according to the present invention;

FIGS. 3 to 6 are views illustrating a first embodiment of a method of manufacturing a needle of a probe card according to the present invention;

FIGS. 7 to 12 are views illustrating a second embodiment of a method of manufacturing a needle of a probe card according to the present invention;

FIGS. 13 to 18 are views illustrating a third embodiment of a method of manufacturing a needle of a probe card according to the present invention;

FIG. 19 is a front view depicting needles whose beam portions has undergone a plating process, which are soldered on a substrate of a probe card; and

FIGS. 20 and 21 are side cross-sectional view and front cross-sectional views depicting a part of needles included in a probe card, according to an embodiment of the present invention.

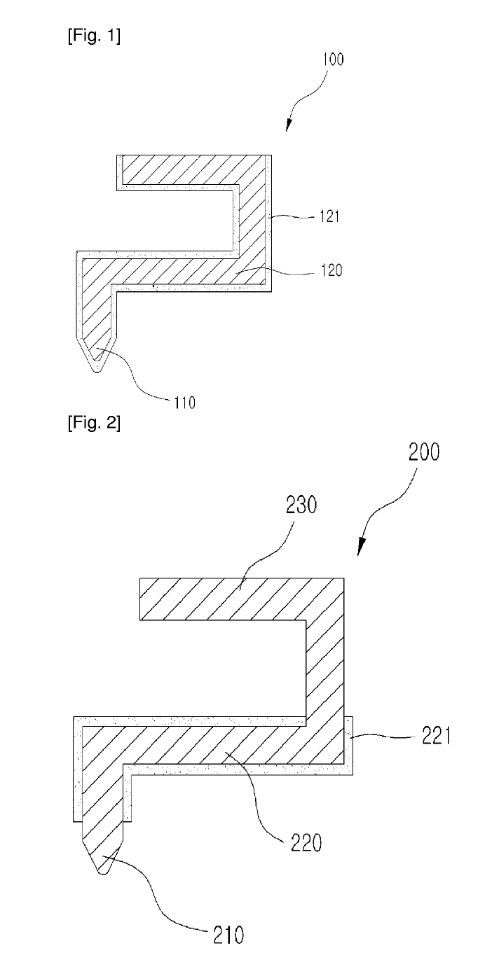

### BRIEF DESCRIPTION OF SYMBOLS IN THE DRAWINGS

200: needle

210: probing portion

220: beam portion

221: plating

230: soldered portion

### BEST MODE FOR CARRYING OUT THE INVENTION

Preferred embodiments according to a needle of a probe card, a probe card, and its manufacturing method of the present invention will be described in detail with reference to the accompanying drawings.

FIG. 2 is a cross-sectional view depicting a needle of a probe card according to the present invention.

The needle 200 of a probe card is configured to include: a probing portion 210 contacting a pad of a wafer die, not shown; a soldered portion 230 soldered to a circuit board (not shown) of the probe card, for transmitting an electrical signal to the probing portion 210; and a beam portion 220 integrally connecting the probing portion 210 and the soldered portion 230 and having elasticity to exhibit a certain pin pressure by which the probing portion 210 can elastically contact the pad of a wafer die. Here, the beam undergoes a plating process to form a plated portion 221 that prevents the probing portion 210 from twisting.

The probing portion 210 is integrally connected to the beam portion 220 and is fabricated to have a pointed end (hereinafter referred to as a tip). The probing portion 210 touches the pad of a wafer die at certain pin pressure. The probing portion 210 does not undergo a plating process, so that its tip is not blunt. Therefore, the area contacting the probing portion 210 and the pad of a wafer remains relatively small.

The soldered portion 230 is soldered with a circuit board of the probe card such that the needle can be attached to the circuit board, thereby allowing electrical signals to transmit between the probe card and the pads of a wafer die. It is preferable that the soldered portion 230 of the needle 200 does not undergo a plating process so that the needle 200 can be easily replaced.

The beam portion 220 is located between the probing portion 210 and the soldered portion 230 and integrally connects the same to support the probing portion 210. Here, the beam portion 220 enables the probing portion 210 to contact the pad of a wafer die at a certain pin pressure caused by its elasticity (i.e., a shape-restoring force). The beam portion 220 undergoes a plating process to form a plated portion 221 that prevents the needle 200 from twisting. The beam portion 220 is plated with preferable conductive metal materials, such as Au, Ni, and Cu, etc, thereby forming a plated portion 221.

As such, since the needle 200 is formed in such a way that its probing portion 210 is not blunt, the contact area of the pad by the probing portion 210 is relatively small. Therefore, event if the beam portion 220 exhibits a relatively small amount of elastic force, the probing potion 210 can contact the pad at a certain level of pin pressure, keeping the test apparatus from malfunctioning. As well, since the beam portion 220 forms a plated portion 221, the needle 200 cannot twist. Consequently, the needle 200 of a probe card can precisely contact the pad of a wafer die consistently, and will not overwork the test apparatus.

The following is a description of embodiments of a method of manufacturing a needle of a probe according to the present invention.

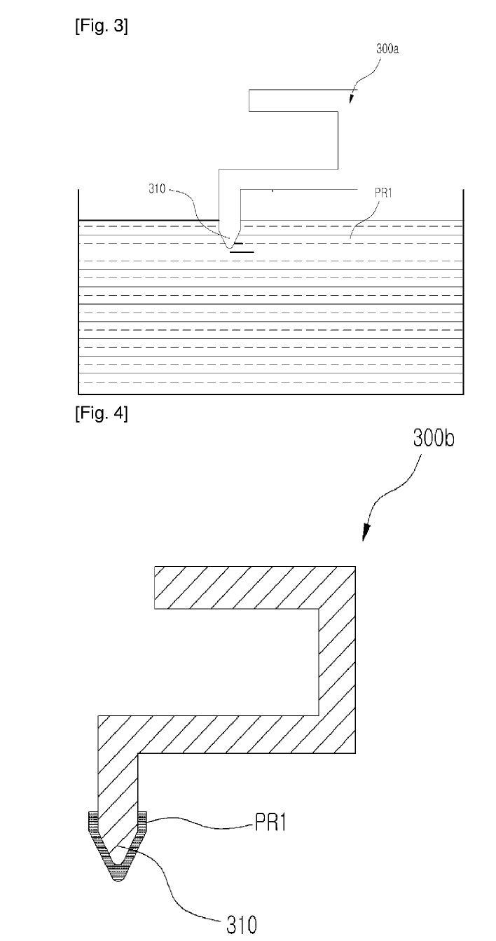

FIGS. 3 to 6 are views illustrating a first embodiment of a method of manufacturing a needle of a probe card according to the present invention.

Firstly, as shown in FIG. 3, a tip portion 310 of a raw body 300a of a needle for a probe card is coated with a photo resist PR1. Similar to the conventional needle of a probe card, the raw body 300a may be preferably made of Ni—W, etc. The photoresist PR1 is implemented by THB-151N (JSR), PMER, AZ9296, etc. After completing the coating of photo resist PR1, a first intermediate body 300b of the needle is fabricated as shown in FIG. 4.

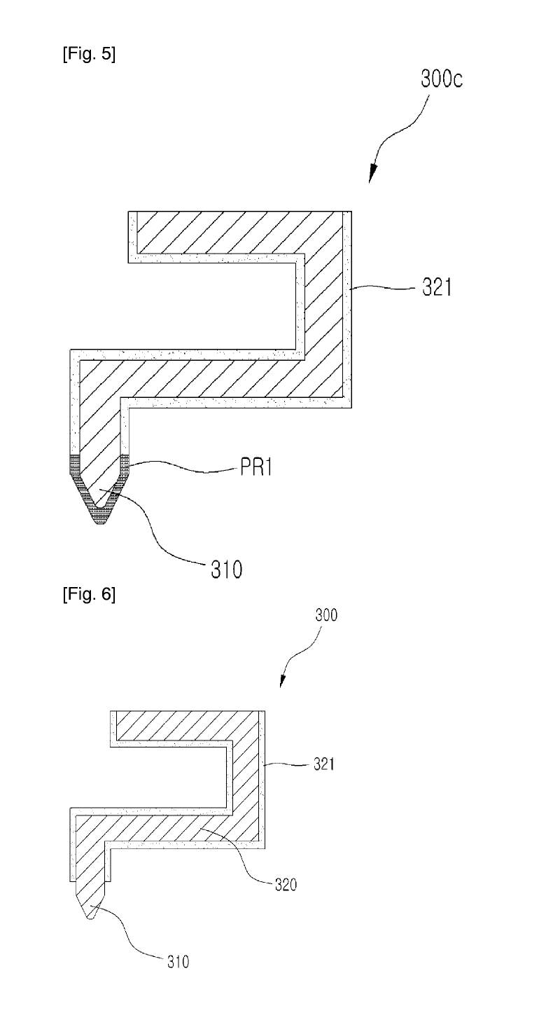

Next, as shown in FIG. 5, the first intermediate body 300b undergoes a plating process to form a plated portion 321. The plated portion 321, as described above, may be formed by a conductive material, such as Au, Ni, and Cu, etc. The photoresist PR1 coated on the first intermediate body 300b serves as a mask that prevents the probing potion 310 from being plated. Consequently, as the first intermediate body 300b of the needle forms the plated portion 321, a second intermediate body 300c is fabricated.

Finally, as shown in FIG. 6, the photoresist PR1 is removed from the probing portion 310 of the second intermediate body 300c of the needle using a photoresist remover. The photoresist remover is implemented by THB-S1, PMER 104, and AZ700k, etc. Since the photoresist PR1 coating the probing portion 310 serves as a mask, the plated portion 310 does not undergo the plating process. Therefore, the needle 300 of a probe card, only whose beam portion 320 has undergone the plating process, is fabricated as shown in FIG. 6.

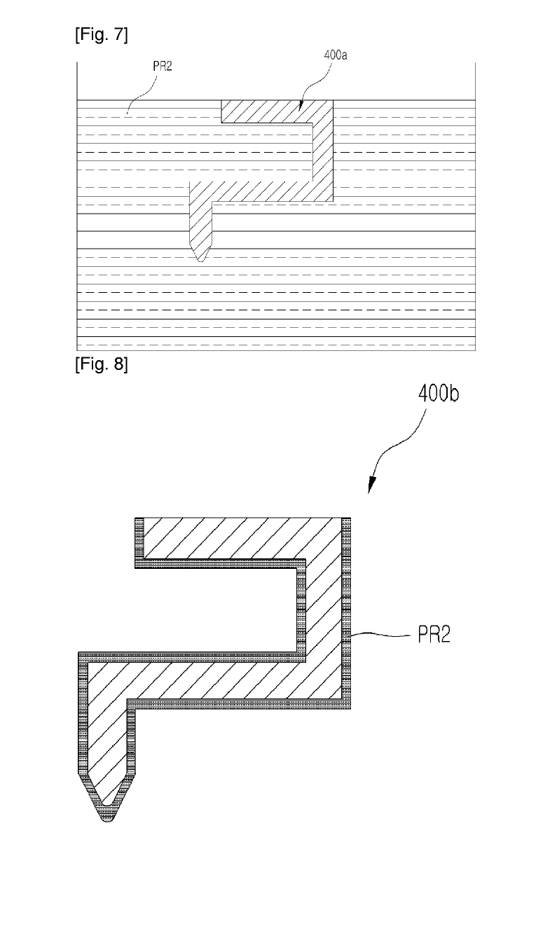

FIGS. 7 to 12 are views illustrating a second embodiment of a method of manufacturing a needle of a probe card according to the present invention.

Firstly, as shown in FIG. 7, a raw body 400a of a needle for a probe card is coated with a photoresist PR2, thereby fabricating a first intermediate body 400b as shown in FIG. 8. Here, the photoresist PR2 may be implemented by employing the same as in first embodiment. The first intermediate body 400b is fabricated in such a way the raw body 400a is entirely coated with the photoresist PR2.

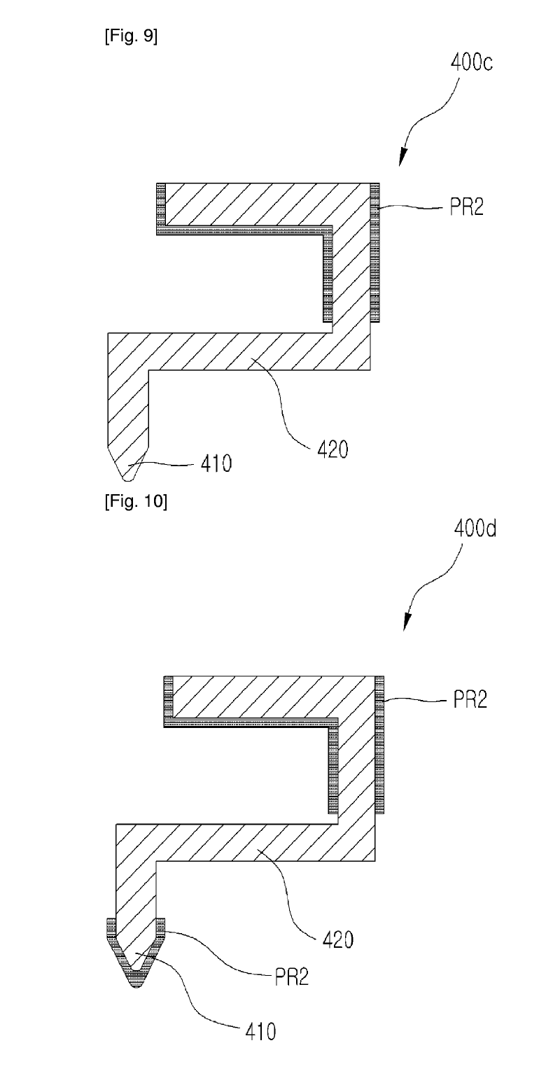

Next, as shown in FIG. 9, the photoresist PR2 is removed from the beam portion 420 and probing portion 410 of the first intermediate body 400b, thereby fabricating a second intermediate body 400c. Here, the remover of the photoresist PR2 may be implemented by employing the same as the first embodiment. As a result, the second intermediate body 400c is formed in such a way that only the soldered portion 430 is coated with the photoresist PR2.

After that, the probing portion 410 of the second intermediate body 400c is coated with the photoresist PR2, thereby fabricating a third intermediate body 400d as shown in FIG. 10. That is, the third intermediate body 400d is formed in such a way that the soldered portion 430 and probing portion 410 are coated with the photoresist PR2.

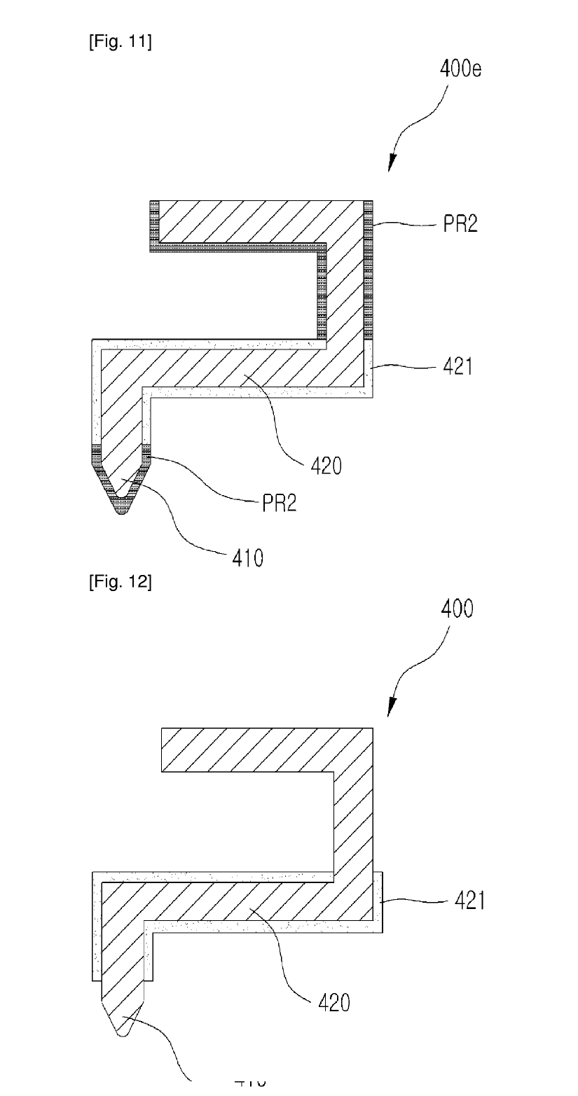

Subsequently, the third intermediate body 400d undergoes a plating process to form a plated portion 421, thereby fabricating a fourth intermediate body 400e as shown in FIG. 11. That is, the fourth intermediate body 400e is fabricated in such a way that only a beam portion 420 undergoes the plating process to form the plated portion 421, because the photoresist PR2 is not on the beam portion 420 of the third intermediate body 400d.

Finally, the photoresist PR2 is removed from the soldered portion 430 and probing portion 410 of the fourth intermediate body 400e using the remover of the photoresist PR2. As a result, the needle 400 of a probe card, whose beam portion 420 only has undergone the plating process, is fabricated as shown in FIG. 12.

FIGS. 13 to 18 are views illustrating a third embodiment of a method of manufacturing a needle of a probe card according to the present invention.

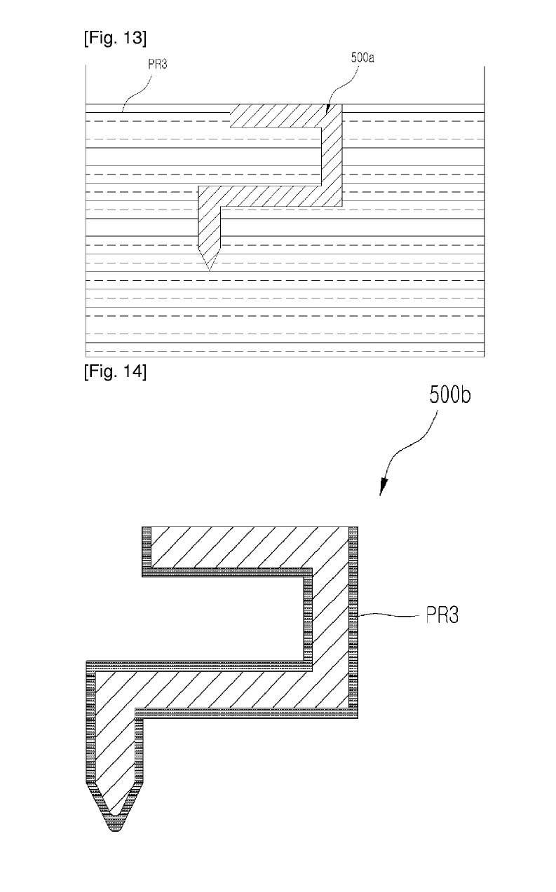

Firstly, as shown in FIG. 13, a raw body 500a of a needle for a probe card is coated with a photoresist PR3, thereby fabricating a first intermediate body 500b as shown in FIG. 14. Here, the photoresist PR3 may be implemented by employing the same as in the former embodiments. The first intermediate body 500b is fabricated in such a way the raw body 500a is entirely coated by the photoresist PR3.

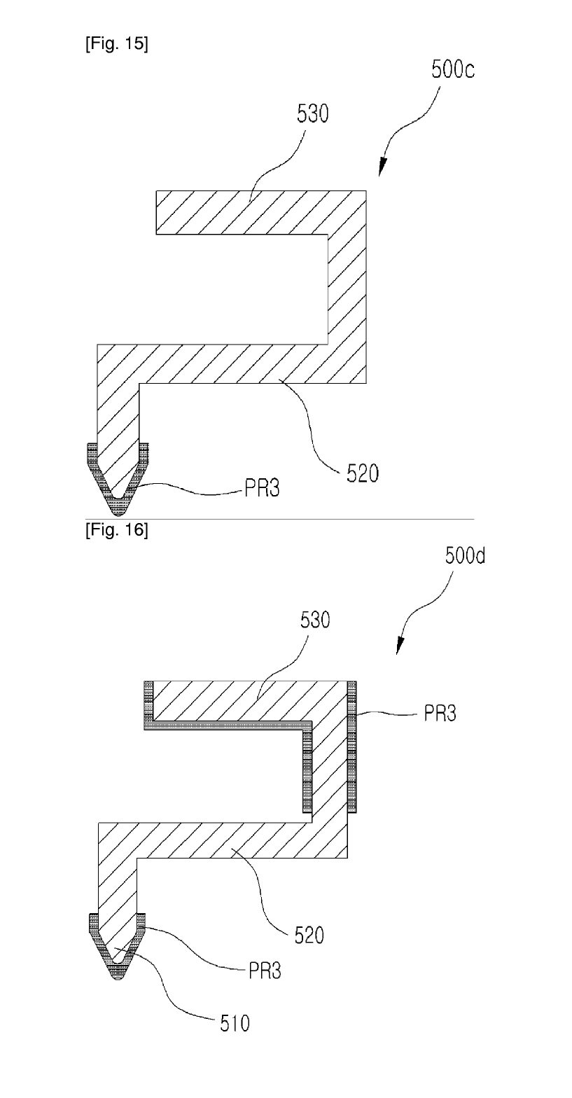

Next, as shown in FIG. 15, the photoresist PR3 is removed from the beam portion 520 and soldered portion 530 of the first intermediate body 500b, thereby fabricating a second intermediate body 500c. Here, the remover of the photoresist PR3 may be implemented by employing the same as the former embodiments. As a result, the second intermediate body 500c is formed in such a way that the photoresist PR3 remains only on the probing portion 510.

After that, a soldered portion 530 of the second intermediate body 500c is coated with the photoresist PR3, thereby fabricating a third intermediate body 500d as shown in FIG. 16. That is, the third intermediate body 500d is formed in such a way that the soldered portion 530 and probing portion 510 are coated with the photoresist PR3.

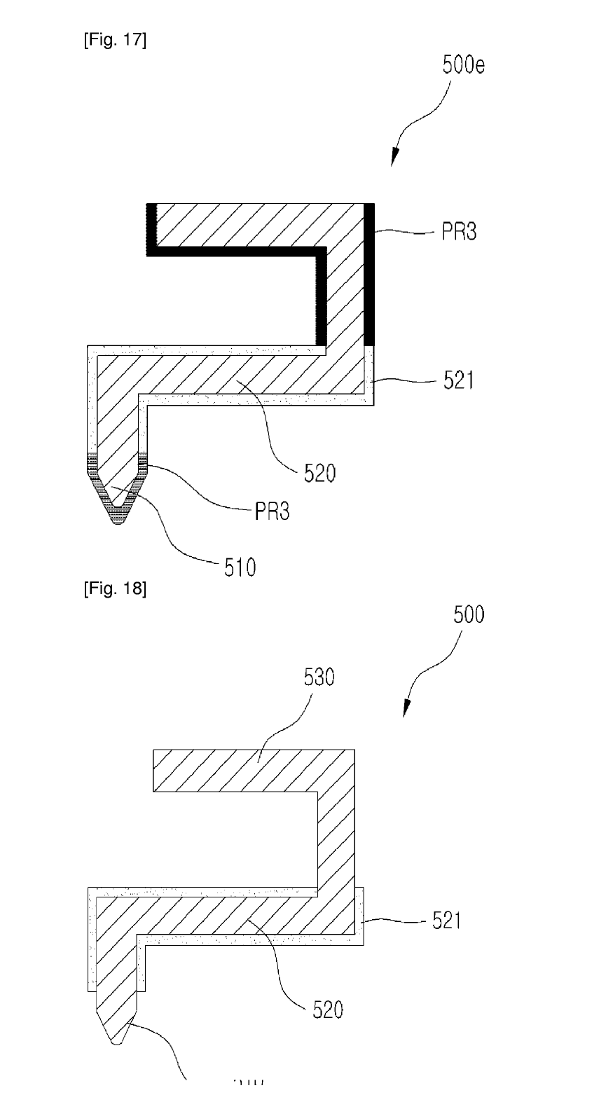

Subsequently, the third intermediate body 500d undergoes a plating process to form a plated portion 521, thereby fabricating a fourth intermediate body 500e as shown in FIG. 17. That is, the fourth intermediate body 500e is fabricated in such a way that only a beam portion 520 undergoes the plating process to form the plated portion 521, because the photoresist PR3 does not exist in the beam portion 520 of the third intermediate body 500d.

Finally, the photoresist PR3 is removed from the soldered portion 530 and probing portion 410 of the fourth intermediate body 500c using the remover of the photoresist PR3. As a result, the needle 500 of a probe cared, whose beam portion 520 only has undergone the plating process, is fabricated as shown in FIG. 18.

The following is a description of a probe card according to the present invention.

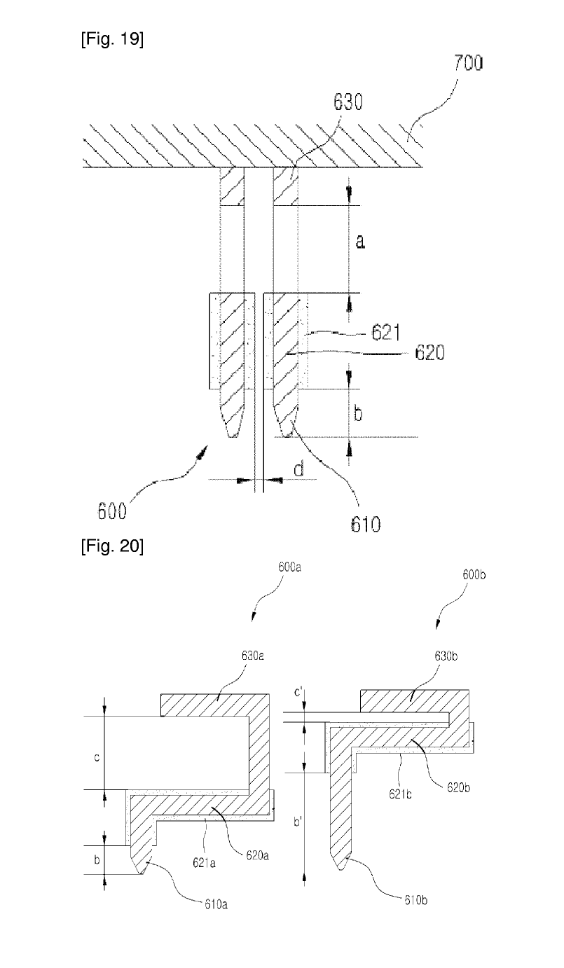

FIG. 19 is a front view depicting needles whose beam portions has undergone a plating process, which are soldered on a substrate of a probe card.

The probe card is configured to include a substrate 700, on which a plurality of circuit patterns are formed, and a plurality of needles 600 soldered to the substrate 700. Each needle 600 is classified into a soldered portion 630 to be soldered to the substrate 700, a beam portion 621 having undergone a plating process to form a plated portion 621, a probing portion 621 of a distance b, and a portion of a height a between the soldered portion and the beam portion 620. Here, all the needles 600 are fabricated in such a way that they have the same height a and have the same height b. As well, the needles are aligned in such a way that their beam portions are very close to each other at an interval d. When the interval d between the beam portions 620 is relatively small, this can cause the needles to mutually interfere with each other.

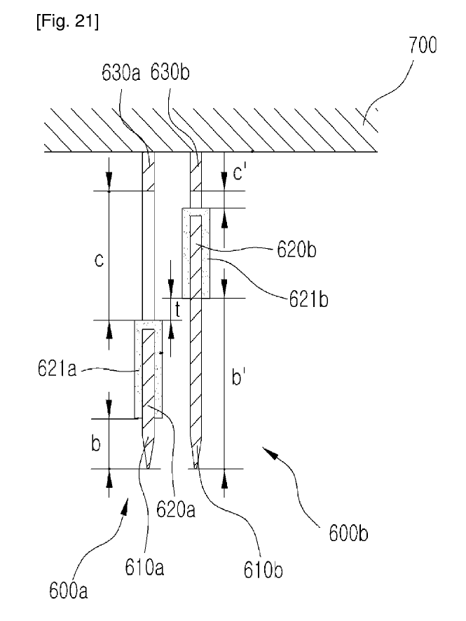

FIGS. 20 and 21 are side cross-sectional view and front cross-sectional view depicting a part of needles included in a probe card, according to an embodiment of the present invention.

The probe card is configured to include a needle 600a and a needle 600b adjacent to the needle 600a (hereinafter referred to as adjacent needle 600b), whose beam portions 620a and 620b are formed at respective positions that are different from each other in height.

Specifically, the probe card aligns the needles 600a and 600b in such a way that the height c from the soldered portion 630a to the beam portion 620a of the needle 600a is different from the height c′ from the soldered portion 630b to the beam portion 620b of the adjacent needle 600b or the distances b of the probing portion 610a of the needle 600a is different from the distance b′ of the proving portion 610b of the needle 600b. That is, the beam portions 620a and 620b are different from each other in their positions occupied in the needles 600a and 600b, respectively.

As is well shown, FIGS. 20 and 21 depict the difference t of the positions (or heights) between the beam portions 620a and 620b of the needle 600a and the adjacent needle 600b.

Since there is the difference t between the positions (heights) of the beam portions 620a and 620b, the probe card accordingly has the following advantages:

The plated portions 621a and 621b formed on the respective beam portions 620a and 620b do not interfere with each other.

As well, the needles 600a and 600b can be highly integrated on the substrate 700, thereby manufacturing a highly needle-integrated probe card.

The probe card according to the present invention may be implemented by two or more types of needles whose beam portion positions are different from each other.

That is, the probe card according to the present invention can be highly integrated by combining various types of needles, thereby conveniently and efficiently testing highly integrated semiconductor devices.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

### INDUSTRIAL APPLICABILITY

The present invention can be widely applied to the test systems for testing semiconductor devices.

1. A needle of a probe card comprising:
a probing portion for contacting a pad of a wafer die at a certain pin pressure;
a soldered portion soldered to a circuit board of the probe card, for transmitting an electrical signal to the probing portion; and
a beam portion integrally connecting the probing portion and the soldered portion and having elasticity to exhibit a certain pin pressure by which the probing portion 210 can elastically contact the pad of a wafer die,
*wherein the beam portion undergoes a plating process.

2. A needle of a probe card comprising:
a probing portion for contacting a pad of a wafer die at a certain pin pressure;
a soldered portion soldered to a circuit board of the probe card, for transmitting an electrical signal to the probing portion; and
a beam portion integrally connecting the probing portion and the soldered portion and having elasticity to exhibit a certain pin pressure by which the probing portion 210 can elastically contact the pad of a wafer die,
wherein the soldered portion and the beam portion undergo a plating process.

3. A method of manufacturing a needle of a probe card comprising:
coating a probing portion of a raw body of the needle with a photoresist to fabricate a first intermediate body;
plating the first intermediate body to fabricating a second intermediate body; and
removing the photoresist from the probing portion of the second intermediate body.

4. A method of manufacturing a needle of a probe card comprising:
coating a raw body of the needle with a photoresist to fabricate a first intermediate body;
removing the photoresist from a beam portion and a probing portion of the first intermediate body of the needle to fabricate a second intermediate body;
coating the probing portion of the second intermediate body of the needle with the photoresist to fabricate a third intermediate body;
plating the third intermediate body of the body to fabricate a fourth intermediate body; and
removing the photoresist from the fourth intermediate body of the needle.

5. A method of manufacturing a needle of a probe card comprising:
coating a raw body of the needle with a photoresist to fabricate a first intermediate body of the needle;
removing the photoresist from a beam portion and a soldered portion of the first intermediate body to fabricate a second intermediate body of the needle;
coating the soldered portion of the second intermediate body with the photoresist to fabricate a third intermediate body of the needle;
plating the third intermediate body to fabricate a fourth intermediate body of the needle; and
removing the photoresist from the fourth intermediate body of the needle.

6. A probe card comprising:
a substrate having a plurality of circuit patterns; and
a plurality of needles electrically connected to the plurality of circuit patterns, wherein each needle comprises:
a probing portion contacting a pad of a wafer die at a certain pin pressure;
a soldered portion soldered to the substrate, for transmitting an electrical signal to the probing portion; and
a beam portion integrally connecting the probing portion and the soldered portion and having an electricity to exhibit a certain pin pressure by which the probing portion 210 can elastically contact the pad of a wafer die, and
wherein the adjacent needles are aligned in such way that their distances between the soldered portion and the beam portion arc located at different positions.

7. The probe card according to claim 6, wherein the beam portions of the plurality of needles undergo a plating process.

8. The probe card according to claim 7, wherein the beam portion of the needle and the adjacent beam portion of the adjacent needle are located at different positions, in which a top position of the beam portion and a bottom position of the adjacent beam portion are spaced apart a certain value.
